(19) United States
(12) Patent Application Publication
(10) Pub. No.: US 2009/0213541 A1
(43) Pub. Date: Aug. 27, 2009

(54) Cooling Plate Assembly with Fixed and Articulated Interfaces, and Method for Producing Same

(76) Inventors: Matthew Allen Butterbaugh, Rochester, MN (US); Maurice Francis Holahan, Lake City, MN (US); Terry L. Lyon, Rochester, MN (US); David Roy Motschman, Rochester, MN (US)

Correspondence Address: Matthew C. Zehrer;IBM Corporation, Dept. 917, 3605 Highway 52 North, Rochesster, MN, 55901-7829, US

(21) Appl. No.: 12/038,227

(22) Filed: Feb. 27, 2008

(51) Int. Cl. H05K 7/20; B21D 39/03

(52) U.S. Cl. 361/689; 361/707; 361/699; 29/428

(57) ABSTRACT

A cooling plate assembly for transferring heat from electronic components mounted on a circuit board includes both fixed and articulated interfaces. A fixed-gap coldplate is positioned over and in thermal contact with (e.g., through an elastomerically compressive pad thermal interface material) electronic components mounted on the circuit board's top surface. An articulated coldplate is positioned over and in thermal contact with at least one electronic component mounted on the circuit board's top surface. In the preferred embodiments, the articulated coldplate is spring-loaded against one or more high power processor components having power dissipation greater than that of the electronic components under the fixed-gap cooling plate. Thermal dissipation channels in the coldplates are interconnected by flexible tubing, such as copper tubing with a free-expansion loop. In the preferred embodiments, the coldplates and the flexible tubing are connected to define a portion of a single flow loop used to circulate cooling fluid through the coldplates.

### BACKGROUND OF THE INVENTION

1. Field of Invention

The present invention relates in general to the field of electronic packaging. More particularly, the present invention relates to electronic packaging that removes heat from a plurality of electronic components using a cooling plate assembly with both fixed and articulated interfaces.

2. Background Art

Electronic components, such a microprocessors and integrated circuits, must operate within certain specified temperature ranges to perform efficiently. Excessive temperature degrades electronic component functional performance, reliability, and life expectancy. Heat sinks are widely used for controlling excessive temperature. Typically, heat sinks are formed with fins, pins or other similar structures to increase the surface area of the heat sink and thereby enhance heat dissipation as air passes over the heat sink. In addition, it is not uncommon for heat sinks to contain high performance structures, such as vapor chambers and/or heat pipes, to enhance heat spreading into the extended area structure. Heat sinks are typically formed of highly conductive metals, such as copper or aluminum. More recently, graphite-based materials have been used for heat sinks because such materials offer several advantages, such as improved thermal conductivity and reduced weight.

Many computer hardware designs for military applications rely on thermal conduction through circuit board copper planes to edge features that clamp to a “wedge lock” device. This wedge lock device then conducts heat from the circuit board to the computer chassis structure which then sheds heat via liquid cooling or convection to the external environment. In some designs, additional heat dissipation is achieved by attaching a cooling plate (also referred to as a “coldplate”) to the backside of the circuit board. The cooling plate, which may be either a thermally conductive plate or a liquid-cooled plate, adds another thermally conductive path to the wedge lock device in parallel with the thermally conductive path through the circuit board itself (i.e., through the circuit board copper planes). These solutions have worked well for circuit board designs with lower power processor components. Typically, such lower power processor components have less than 20 W power dissipation.

More recent computer hardware designs for military applications are starting to utilize high power processor components (e.g., in excess of 90 W power dissipation). With this much higher heat load, the traditional method of sinking heat through the electronic component interconnect and through the circuit board copper planes, as well as through the backside coldplate, does not provide a low enough thermal resistance path. Accordingly, this much higher heat load will result in a processor junction temperature that exceeds acceptable temperature limits for system functionality and reliability.

In order to sufficiently cool such higher power electronic components to acceptable temperatures, the heat must be drawn directly off the top surface of the component, instead of through the interconnect (bottom) side. Removing heat from the component topside, either by conduction through a thermally conductive cooling plate to the computer chassis structure or via fluid convection through an attached liquid-cooled cooling plate, results in a much lower thermal resistance path to the external environment.

Current solutions for topside cooling in this type of military application incorporate a coldplate (i.e., either a thermally conductive cooling plate or fluid-cooled cooling plate) that is hard mounted to the processor circuit board. Typically, one or more high power processors to be cooled is/are mounted on the topside of the processor circuit board, along with a plurality of other electronic components that are to be cooled. These current solutions utilize a fixed-gap coldplate, i.e., the coldplate is fixedly mounted to the processor circuit board so as to present a fixed-gap interface between the coldplate and each of the components to be cooled. Because typical IC (integrated circuit) components have a component height variation on the order of ±0.25 mm or greater, the accumulation of tolerances in this design requires a large gap (i.e., interface thickness) in the form of a thick layer of compressive or elastomeric pad TIM (thermal interface material). Unfortunately, the utilization of a thick layer of compressive pad TIM in the requisite large gap will not enable a high performance interface needed for the high power processors now desired for military applications.

A fixed-gap coldplate will provide acceptable thermal performance if the high power processor parts are screen-sorted for package height to achieve an acceptably thin bondline (i.e., the TIM gap between coldplate and each high power processor). However, screening parts for package height is undesirable due to the loss in yield of relatively expensive parts

Another option is to create a custom fixed-gap coldplate for each individual circuit board assembly. In order to implement this option, each circuit board assembly that is built must be inspected to determine one or more critical package heights (e.g., the height of each high power processor) and then the coldplate is custom milled to match the inspected circuit board assembly to create the desired TIM gap between the critical component and the coldplate. A similar option is to use custom shims to create the desired TIM gap between the critical component and the coldplate. Both of these options drive higher cost in manufacturing due to the need for customization of each processor circuit board over the life of the product build cycle. In addition, the need for customization makes maintenance in the field difficult because neither the critical components nor the coldplate can be replaced with standard parts.

Yet another option is to use a single articulated-gap coldplate, i.e., a coldplate that is spring-loaded against the topside of the components to be cooled. This option draws on technology used in high performance business servers, where it is not uncommon to achieve a very thin high-performance interface by spring loading a heatsink against the top surface of a module (i.e., a single-chip module (SCM) or a multi-chip module (MCM)) having one or more high power processor components. However, it is difficult to apply this single articulated-gap coldplate option to applications where numerous components are to be cooled and/or the components to be cooled are spread over a large region of the processor circuit board. Moreover, the larger the region of the processor circuit board populated by the components to be cooled, the larger the mass of the articulated-gap cooling plate. An articulated-gap cooling plate having a large mass is undesirable in military and other applications that require operation in high g-force environments (e.g., fighter aircraft, space vehicles, and the like) because high g-forces may cause the cooling plate to momentarily pull away from the components to be cooled (reducing the performance of the interface by introduction of air gap from voids or delamination) and then be forced back into contact with those components (possibly damaging the components).

These defects may be addressed through the use of multiple articulated-gap coldplates, i.e., individual articulated-gap coldplates separately spring-loaded against the top side of each component (or module) to be cooled. These individual articulated-gap coldplates are interconnected with flexible tubing between each coldplate. Such a scheme is disclosed in U.S. patent application Ser. No. 11/620,088, filed Jan. 5, 2007, entitled “METHODS FOR CONFIGURING TUBING FOR INTERCONNECTING IN-SERIES MULTIPLE LIQUID-COOLED COLD PLATES”, assigned to the same assignee as the present application, and hereby incorporated herein by reference in its entirety. While this option allows for mechanically independent attach solutions for each coldplate/component (or module) combination and allows each coldplate to have a relatively small mass, it greatly increases the risk of leaking, given the large number of flexible tube interconnects. Such an increase in the risk of coolant leaking from the tubing increases the risk of component failure, and increases the risk of fire if the coolant is flammable.

Therefore, a need exists for an enhanced method and apparatus for removing heat from electronic components mounted on a circuit board.

### SUMMARY OF THE INVENTION

According to the preferred embodiments of the present invention, a cooling plate assembly for transferring heat from electronic components mounted on a circuit board includes both fixed and articulated interfaces. A fixed-gap coldplate is positioned over and in thermal contact with (e.g., through an elastomerically compressive pad thermal interface material) electronic components mounted on the circuit board's top surface. An articulated coldplate is positioned over and in thermal contact with at least one electronic component mounted on the circuit board's top surface. In the preferred embodiments, the articulated coldplate is spring-loaded against one or more high power processor components having power dissipation greater than that of the electronic components under the fixed-gap cooling plate. Thermal dissipation channels in the coldplates are interconnected by flexible tubing, such as copper tubing with a free-expansion loop. In the preferred embodiments, the coldplates and the flexible tubing are connected to define a portion of a single flow loop used to circulate cooling fluid through the coldplates.

### BRIEF DESCRIPTION OF THE DRAWINGS

The preferred exemplary embodiments of the present invention will hereinafter be described in conjunction with the appended drawings, where like designations denote like elements.

FIG. 1 is a top plan view of a cooling plate assembly according to the preferred embodiments of the present invention.

FIG. 2 is a sectional view of an articulated cooling plate portion of the cooling plate assembly shown in FIG. 1.

FIG. 3 is a sectional view of a fixed-gap cooling plate portion of the cooling plate assembly shown in FIG. 1.

FIG. 4 is a sectional view of a fixed-gap cooling plate portion of a modified version of the cooling plate assembly shown in FIG. 1.

FIG. 5 is a top plan view of a cooling plate assembly having fixed-gap cooling plate and an articulated cooling plate in fluid communication with a reservoir containing cooling fluid according to the preferred embodiments of the present invention.

FIG. 6 is a flow diagram of a method for attaching a heat transfer assembly having fixed and articulated interfaces to a circuit board according to the preferred embodiments of the present invention.

### DETAILED DESCRIPTION OF THE PREFERRED EMBODIMENTS

1. Overview

In accordance with the preferred embodiments of the present invention, a cooling plate assembly for transferring heat from electronic components mounted on a circuit board includes both fixed and articulated interfaces. A fixed-gap coldplate is positioned over and in thermal contact with (e.g., through an elastomerically compressive pad thermal interface material) electronic components mounted on the circuit board's top surface. An articulated coldplate is positioned over and in thermal contact with at least one electronic component mounted on the circuit board's top surface. In the preferred embodiments, the articulated coldplate is spring-loaded against one or more high power processor components having power dissipation greater than that of the electronic components under the fixed-gap cooling plate. Thermal dissipation channels in the coldplates are interconnected by flexible tubing, such as copper tubing with a free-expansion loop. In the preferred embodiments, the coldplates and the flexible tubing are connected to define a portion of a single flow loop used to circulate cooling fluid through the coldplates. The minimal number of flexible tube interconnects needed to implement a cooling plate assembly in accordance with the preferred embodiments of the present invention not only decreases the risk of leaking (as compared to solutions that require a large number of flexible tube interconnects) and hence decreases the risk of component failure but also decreases the risk of fire if the cooling fluid is flammable.

2. Detailed Description

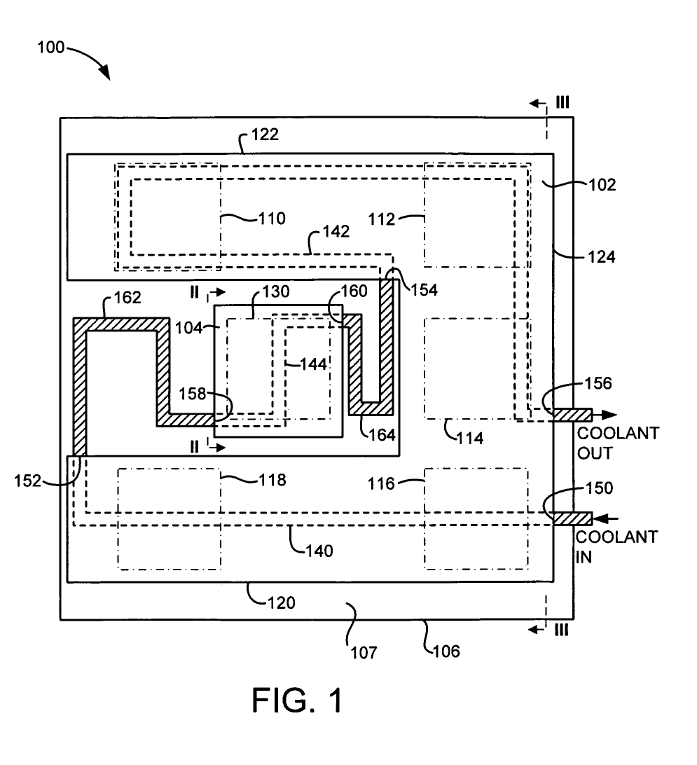

Referring now to FIG. 1, there is depicted, in a top plan view, a cooling plate assembly 100 that utilizes a fixed-gap cooling plate 102 (also referred to herein as a “fixed-gap coldplate”) and an articulated cooling plate 104 (also referred to herein as an “articulated coldplate” or a “floating coldplate”) according to the preferred embodiments of the present invention. Preferably, the fixed-gap cooling plate 102 is “fixedly” mounted to a printed circuit board (PCB) 106 using a relatively thick compliant thermal interface material, while the articulated cooling plate 104 is gimbal-mounted to the PCB 106 using a relatively high performance interface with low thickness and high contact pressure provided by a spring loading mechanism. One or more electronic components to be cooled by the fixed-gap cooling plate 102 is/are mounted on the top surface 107 of the PCB 106, as is one or more electronic components to be cooled by the articulated cooling plate 104. In addition, the fixed-gap cooling plate 102 may be used to cool one or more electronic components mounted on the bottom surface of the PCB 106.

In the embodiment shown in FIG. 1, the fixed-gap cooling plate 102 provides cooling for electronic components 110, 112, 114, 116 and 118 (shown as phantom lines in FIG. 1), which are preferably lower power components, such as low power processors, field programmable gate arrays (FPGAs), memory arrays, modules with one or more chips, and the like. In the embodiment shown in FIG. 1, the fixed-gap cooling plate 102 has a generally U-shaped configuration that includes two leg portions 120, 122 each extending from a base portion 124. One skilled in the art will appreciate that the configuration of the fixed-gap cooling plate 102 shown in FIG. 1 is exemplary and that a fixed-gap cooling plate in accordance with the present invention may be configured to have any shape. Likewise, a fixed-gap cooling plate in accordance with the preferred embodiments of the present invention may provide cooling for any number and any type of electronic components. In accordance with the preferred embodiments of the present invention, the electronic components cooled by the fixed-gap cooling plate 102 have relatively low power dissipation (e.g., <20 W) as compared to the relatively high power dissipation (e.g., ≧90 W) of the one or more electronic components cooled by the articulated cooling plate 104, i.e., electronic component 130.

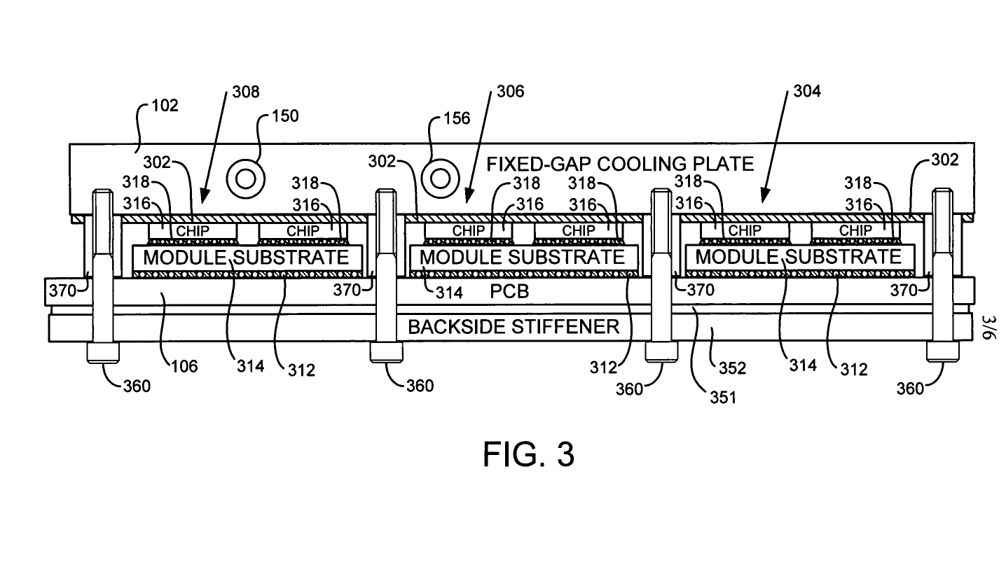

In accordance with the preferred embodiments of the present invention, the electronic components cooled by the fixed-gap cooling plate 102 are in thermal contact with the fixed-gap cooling plate 102 through a compressive pad thermal interface material (TIM) 302 (shown in FIG. 3). The compressive pad TIM may be a re-usable elastomerically conformable type, or it may be pre-cured or, alternatively, may be cured in-situ. For example, the compressive pad TIM may be provided by mixing a multi-part liquid material and then applying the mixture to the fixed-gap cooling plate 102 and/or the electronic components. An example of a suitable composition for the compressive pad TIM is a fiberglass reinforced, thermally conductive silicone gel pad (commercially available from Dow Coming Corporation, Midland, Mich.).

In the embodiment shown in FIG. 1, the articulated cooling plate 104 has a substantially rectangular configuration and is substantially surrounded by the fixed-gap cooling plate 102. That is, the articulated cooling plate 104 is positioned between the leg portions 120, 122 of the fixed-gap cooling plate 102 and adjacent the base portion 124 of the fixed-gap cooling plate 102. One skilled in the art will appreciate that the configuration of the articulated cooling plate 104 is exemplary, as is the positioning of the articulated cooling plate 104 relative to the fixed-gap cooling plate 102, and that an articulated cooling plate in accordance with the present invention may be configured to have any shape and position relative to the fixed-gap cooling plate. The articulated cooling plate 104 provides cooling for a high power electronic component 130 (shown as phantom lines in FIG. 1), which is preferably a high power processor, a module with one or more high power processor chips, and the like having a relatively high power dissipation (e.g., ≧90 W). One skilled in the art will appreciate that an articulated cooling plate in accordance with the preferred embodiments of the present invention may provide cooling for any number and any type of electronic components.

In accordance with the preferred embodiments of the present invention, a single coolant channel connects the fixed-gap cooling plate to the articulated cooling plate. In the embodiment shown in FIG. 1, the fixed-gap cooling plate 104 includes thermal dissipation channels 140 and 142, while the articulated cooling plate 106 includes a thermal dissipation channel 144. The thermal dissipation channel 140 extends through a lower-side (as viewed in FIG. 1) of the fixed-gap cooling plate 102 from an inlet port 150 at the base portion 124 to an outlet port 152 at the leg portion 120. The thermal dissipation channel 142 extends through an upper-side (as viewed in FIG. 1) of the fixed-gap cooling plate 102 from an inlet port 154 at the leg portion 122 to an outlet port 156 at the base portion 124. The thermal dissipation channel 144 extends through the articulated cooling plate 104 from an inlet port 158 to an outlet port 160.

In the embodiment shown in FIG. 1, a flexible tube 162 interconnects the outlet port 152 of the thermal dissipation channel 140 of the fixed-gap cooling plate 102 to the inlet port 158 of the thermal dissipation channel 144 of the articulated cooling plate 104. Similarly, a flexible tube 164 interconnects the outlet port 160 of the thermal dissipation channel 144 of the articulated cooling plate 104 to the inlet port 154 of the thermal dissipation channel 142 of the fixed-gap cooling plate 102. The flexible tubes 162 and 164 are sufficiently flexible to accommodate various height and tilt tolerance (e.g., sometimes referred to as “gimballing”) that may exist between the fixed-gap cooling plate 102 and the articulated cooling plate 104. Preferably, the flexible tubes 162 and 164 are made of a high thermal conductivity material, such as copper, aluminum, stainless steel, or other metal.

The flexible tubes 162 and 164 preferably each are fabricated from low modulus metal tubing (e.g., 5-10 mm diameter copper tubing) that is bent to form a free-expansion loop. The free-expansion loop increases the length of the tube and thereby enhances the tube's flexibility as compared to a shorter, more directly routed tube. The free-expansion loop enhances the ability of the tube to accommodate relative movement between the cooling plates (e.g., during attachment of the cooling plates to the printed circuit board) while imparting a relatively low reaction force in response to that relative movement.

The flexible tubes 162 and 164 may be connected to the fixed-gap cooling plate 102 and the articulated cooling plate 104 using any suitable conventional fastening technique. The fastening technique preferably also serves to effectively seal the tubes relative to the cooling plates to prevent coolant leaks. The minimal number of flexible tube interconnects needed to implement a cooling plate assembly in accordance with the preferred embodiments of the present invention not only decreases the risk of leaking (as compared to solutions that require a large number of flexible tube interconnects) and hence decreases the risk of component failure but also decreases the risk of fire if the coolant is flammable.

Preferably, a heat transfer assembly, which includes the fixed-gap cooling plate 102, the articulated plate 104, and the flexible tubes 162 and 164, is fabricated first and then the heat transfer assembly is attached to the PCB 106.

Brazing is an example of a suitable conventional fastening technique that may be utilized in connecting the flexible tubes to the cooling plates. For example, the ends of the flexible tube 162 may be slid over and in turn brazed to two press-fit fittings (not shown) respectively provided on the outlet port 152 of the thermal dissipation channel 140 of the fixed-gap cooling plate 102 and the inlet port 158 of the thermal dissipation channel 144 of the articulated cooling plate 104. Similarly, the ends of the flexible tube 164 may be slid over and in turn brazed to two press-fit fittings (not shown) respectively provided on the outlet port 160 of the thermal dissipation channel 144 of the articulated cooling plate 104 and the inlet port 154 of the thermal dissipation channel 142 of the fixed-gap cooling plate 102.

Swaging is another example of a suitable conventional fastening technique that may be utilized in connecting the flexible tubes to the cooling plates. For example, the ends of the flexible tubes may be swaged into grooves extruded into the ports of the cooling plates' thermal dissipation channels.

Preferably, the fixed-gap cooling plate 102 and the articulated cooling plate 104 are made of a high thermal conductivity material, such as copper, aluminum, stainless steel, or other metal. In some embodiments, the fixed-cooling plate 102 and/or the articulated cooling plate 104 may be made of silicon (e.g., single-crystal silicon or polycrystalline silicon) to match the coefficient of thermal expansion of the silicon chips being cooled.

The fixed-gap cooling plate 102 and the articulated cooling plate 104 preferably have a multi-part construction to facilitate the formation of the thermal dissipation channels 140, 142 and 144. For example, each of the cooling plates may be constructed by joining a top plate to a bottom plate, at least one of which has at least a portion of one or more thermal dissipation channels formed on a surface thereof at the interface between top plate and the bottom plate. The top plate and the bottom plate may be joined together using any suitable conventional fastening technique such as brazing, soldering, diffusion bonding, adhesive bonding, etc. For example the top plate may be bonded to the bottom plate using a silver filled epoxy, filled polymer adhesive, filled thermoplastic or solder, or other thermally conductive bonding material. The fastening technique preferably also serves to effectively seal the plates together to prevent coolant leaks.

The thermal dissipation channels may be formed on the surface of either or both the top plate and the bottom plate by any suitable conventional technique such as routing, sawing or other milling technique, or by etching.

Those skilled in the art will appreciate that the thermal dissipation channels are not limited to the simple passages shown in FIG. 1. For example, at least a portion of one or more of the thermal dissipation channels may take the form of a plurality of high-aspect-ratio grooves (e.g., “microfluidic channels”) that extend between a manifold and a plenum. Such a scheme is disclosed in U.S. Patent Application Publication No. 2006/0071326 A1, published Apr. 6, 2006, entitled “INTEGRATED MICRO CHANNELS AND MANIFOLD/PLENUM USING SEPARATE SILICON OR LOW-COST POLYCRYSTALLINE SILICON”, assigned to Intel Corporation, which is hereby incorporated herein by reference in its entirety.

In lieu of a multi-part construction, the fixed-gap cooling plate 102 and/or the articulated cooling plate 104 may have a one-piece construction. For example, the thermal dissipation channels may be formed in the fixed-gap cooling plate 102 and/or the articulated cooling plate 104 through a milling operation (e.g., drilling).

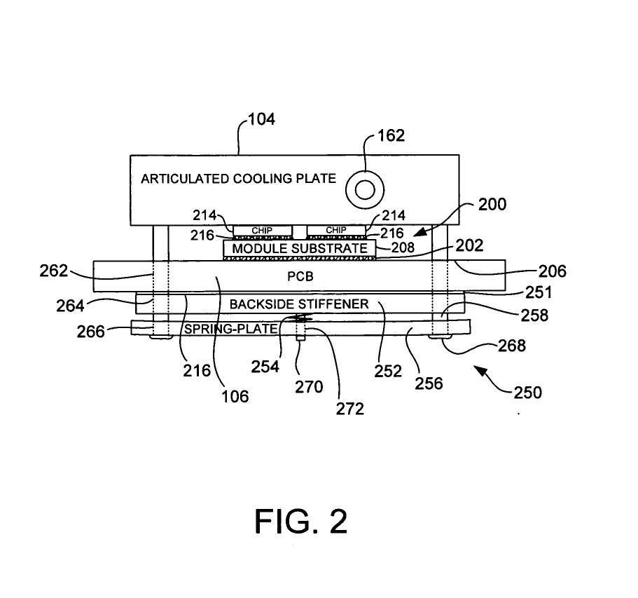

FIG. 2 is a sectional view of an articulated cooling plate portion of the cooling plate assembly shown in FIG. 1, along section line II-II. A multi-chip module assembly 200 shown in FIG. 2 corresponds to the high power electronic component 130 shown in FIG. 1. It is important to note, however, the multi-chip module assembly 200 shown in FIG. 2 is exemplary. Those skilled in the art will appreciate that the methods and apparatus of the present invention can also apply to configurations differing from the multi-chip module assembly shown in FIG. 2, to other types of chip modules, and generally to electronic components. For example, in lieu of being applied to a multi-chip module assembly, the methods and apparatus of the present invention can also be applied to a single-chip module or other electronic component. Also, in lieu of being applied to a multi-chip module assembly that utilizes C4 connectors and a land grid array (LGA) connector, such as shown in FIG. 2, the methods and apparatus of the present invention can also be applied to a multi-chip module assembly that utilizes other connector types. Moreover, in lieu of being applied to a “bare die module”, such as shown in FIG. 2, the methods and apparatus of the present invention can also be applied to a “capped module” or “lidded module” that includes a cap or lid.

The multi-chip module assembly 200 includes a bare die module electrically connected to the printed circuit board (PCB) 106. In the embodiment shown in FIG. 2, the bare die module includes a land grid array (LGA) interposer 202, a module substrate 208, four bare die chips 214 (only two of which are visible in FIG. 2), and controlled collapse chip connection (C4) solder joints 216. The bare die chips 214 may, for example, be flip-chips each placed on a different quadrant of the module substrate 208.

Although not shown for the sake of clarity, a perimeter support/seal may surround the flip-chips 214 and extend between the articulated cooling plate 104 and the PCB 106.

Generally, in connecting an electronic module to a PCB, a plurality of individual electrical contacts on the base of the electronic module must be connected to a plurality of corresponding individual electrical contacts on the PCB. Various technologies well known in the art are used to electrically connect the set of contacts on the PCB and the electronic module contacts. These technologies include land grid array (LGA), ball grid array (BGA), column grid array (CGA), pin grid array (PGA), solder column connect (SCC), and the like. In the illustrative example shown in FIG. 2, an LGA interposer 202 electrically connects PCB 106 to a module substrate 208. The LGA interposer 202 may comprise, for example, conductive elements, such as fuzz buttons, provided in a non-conductive interposer structure. One skilled in the art will appreciate, however, that any of the various other technologies may be used in lieu of, or in addition to, such LGA technology. Although the preferred embodiments of the present invention are described herein within the context of a land grid array (LGA) connector that connects an electronic module to a PCB, one skilled in the art will appreciate that many variations are possible within the scope of the present invention.

Typically, the module substrate 208 is fabricated from a ceramic material and includes conductive attach pads on upper and lower surfaces that are interconnected through conductive vias that extend through the ceramic material.

The articulated cooling plate 104 is spring-biased against the bare die chips 214 (or module cap or lid), typically through a very thin layer (e.g., 30-50 microns) of a thermal interface material (TIM) such as a thermal grease.

The bare die chips 214 are electrically connected to the module substrate 208 by, for example, controlled collapse chip connection (C4) solder joints 216. The C4 solder joints 216 include solder balls that electronically connect terminals (not shown) on the flip-chips 214 to corresponding attach pads (not shown) on the module substrate 208. Typically, a non-conductive polymer underfill that encapsulates the C4 solder joints 216 is disposed in the space between the base of each flip-chip 214 and the upper surface of the module substrate 208. One skilled in the art will appreciate, however, that any of the various other technologies may be used in lieu of, or in addition to, such C4 solder joint connector technology. Although the preferred embodiments of the present invention are described herein within the context of C4 solder joint connectors that connect bare die chips to a module substrate, one skilled in the art will appreciate that many variations are possible within the scope of the present invention.

Electronic components are generally packaged using electronic packages (i.e., modules) that include a module substrate, such as module substrate 208, to which the electronic component is electronically connected. In some cases, the module includes a cap (i.e., capped module) or lid (i.e., lidded module) which seals the electronic component within the module. In other cases, the module does not include a cap (i.e., a bare die module). In the case of a capped module (or a lidded module), the coldplate is typically attached with a thermal interface between a bottom surface of the coldplate and a top surface of the cap (or lid), and another thermal interface between a bottom surface of the cap (or lid) and a top surface of the electronic component. In the case of a bare die module, a coldplate is typically attached with a thermal interface between a bottom surface of the coldplate and a top surface of the electronic component.

In addition, a heat spreader (not shown) may be attached to the top surface of each flip-chip to expand the surface area of thermal interface relative to the surface area of the flip-chip. The heat spreader, which is typically made of a highly thermally conductive material such as SiC or copper, is typically adhered to the top surface of the flip-chip with a thermally-conductive adhesive.

Referring again to FIG. 2, a rigid insulator 251 is disposed along the bottom surface of PCB 106 and is preferably fabricated from fiberglass reinforced epoxy resin. Rigid insulator 251 is urged upwards against PCB 106, and PCB 106 is thereby urged upward towards interposer 202 and module substrate 208, by a clamping mechanism. Preferably, the clamping mechanism is a post/spring-plate type clamping mechanism 250 as shown in FIG. 2. Because such clamping mechanisms are conventional, the post/spring-plate type clamping mechanism 250 is only briefly described below. Additional details about post/spring-plate type clamping mechanisms may be found in U.S. Pat. No. 6,386,890 to Bhatt et al., which is hereby incorporated herein by reference.

One skilled in the art will appreciate that any of the many different types and configurations of clamping mechanisms known in the art may be used in lieu of the post/spring-plate type clamping mechanism 250 shown in FIG. 2. For example, in lieu of a clamping mechanism having bottom side actuation as shown in FIG. 2 it may be desirable to utilize a clamping mechanism with topside actuation as disclosed in U.S. Patent Application Publication No. 2007/0035937 A1, published Feb. 15, 2007, entitled “METHOD AND APPARATUS FOR MOUNTING A HEAT SINK IN THERMAL CONTACT WITH AN ELECTRONIC COMPONENT”, assigned to IBM Corporation, and which is hereby incorporated herein by reference in its entirety.

In the embodiment shown in FIG. 2, clamping mechanism 250 includes a backside stiffener 252, which is preferably a metal or steel plate. An upward force is generated by a spring 254, which directs force upward against stiffener 252 through interaction with a spring-plate 256. It is preferred that spring-plate 256 is a square structure with about the same overall footprint depth as the articulated cooling plate 104. Four cylindrical posts 258 are connected at the four corners of the articulated cooling plate 104 and disposed through cylindrical PCB post apertures 262, post apertures in insulator 251, stiffener post apertures 264, and spring-plate post apertures 266. Post mushroom heads 268 are formed at the ends of posts 258. The post mushroom heads 268 rest against the spring-plate 256 and thereby prevent spring-plate 256 from moving downward. Downward expansion or deflection forces from spring 254 are exerted directly upon spring-plate 256, which translates the forces through posts 258, articulated cooling plate 104, bare die 214 (or module cap or lid) into module substrate 208, thereby forcing module substrate 208 downward until module substrate 208 comes into contact with and exerts force upon the interposer 202. Similarly, force from spring 254 is also exerted upwards by spring 254 and translated through stiffener 252 and insulator 251 into PCB 106, forcing PCB 106 upwards until PCB 106 comes into contact with and exerts force upon the interposer 202. Accordingly, PCB 106 and module substrate 208 are forced toward each other with compressive forces upon interposer 202 disposed therebetween.

Spring-plate 256 also has a threaded screw 270 in the center of spring 254. When screw 270 is turned clockwise, its threads travel along corresponding thread grooves in a spring-plate screw aperture 272 in spring-plate 256 and, accordingly, screw 270 moves upward toward and against stiffener 252. As screw 270 engages stiffener 252 and exerts force upward against it, corresponding relational force is exerted by the threads of screw 270 downward against the thread grooves in spring-plate 256. As illustrated above in the discussion of spring 254, the downward force exerted by screw 270 is translated by spring-plate 256, post mushroom heads 268, posts 258, articulated cooling plate 104 and the bare die 214 (or module cap or lid) into module substrate 208, thereby forcing module substrate 208 downward until module substrate 208 comes into contact with and exerts force upon the interposer 202. Similarly, upward force from screw 270 is translated through stiffener 252 and insulator 251 into PCB 106, forcing PCB 106 upwards until PCB 106 comes into contact with and exerts force upon the interposer 202. Accordingly, after screw 270 is rotated clockwise into contact with stiffener 252, additional clockwise rotation of screw 270 results in increasing compressive force exerted by PCB 106 and module substrate 208 upon interposer 202 disposed therebetween.

FIG. 3 is a sectional view of a fixed-gap cooling plate portion of the cooling plate assembly shown in FIG. 1, along section line III-III. Multi-chip module assemblies 304, 306 and 308 shown in FIG. 3 respectively correspond to the low power electronic components 112, 114 and 116 shown in FIG. 1. It is important to note, however, the multi-chip module assemblies 304, 306 and 308 shown in FIG. 3 are exemplary. Those skilled in the art will appreciate that the methods and apparatus of the present invention can also apply to configurations differing from the multi-chip module assemblies shown in FIG. 3, to other types of chip modules, and generally to electronic components. For example, in lieu of being applied to multi-chip module assemblies, the methods and apparatus of the present invention can also be applied to one or more single-chip modules or other electronic components. Also, in lieu of being applied to multi-chip module assemblies that utilize C4 connectors and land grid array (LGA) connectors, such as shown in FIG. 3, the methods and apparatus of the present invention can also be applied to one or more multi-chip module assemblies that utilizes other connector types. Moreover, in lieu of being applied to “bare die modules”, such as shown in FIG. 3, the methods and apparatus of the present invention can also be applied to one or more “capped modules” or “lidded modules” that each includes a cap or lid.

The multi-chip module assemblies 304, 306 and 308 each include a bare die module electrically connected to the printed circuit board (PCB) 106. In the embodiment shown in FIG. 3, each bare die module includes a land grid array (LGA) interposer 312, a module substrate 314, four bare die chips 316 (only two of which are visible in FIG. 3), and controlled collapse chip connection (C4) solder joints 318. The bare die chips 316 may, for example, be flip-chips each placed on a different quadrant of the module substrate 314.

Although not shown for the sake of clarity, a perimeter support/seal may surround the flip-chips 316 of each module and extend between the fixed-gap cooling plate 102 and the PCB 106.

Generally, as mentioned above, in connecting an electronic module to a PCB, a plurality of individual electrical contacts on the base of the electronic module must be connected to a plurality of corresponding individual electrical contacts on the PCB. Various technologies well known in the art are used to electrically connect the set of contacts on the PCB and the electronic module contacts. These technologies include land grid array (LGA), ball grid array (BGA), column grid array (CGA), pin grid array (PGA), and the like. In the illustrative example shown in FIG. 3, each LGA interposer 312 electrically connects the PCB 106 to a module substrate 314. Each LGA interposer 312 may comprise, for example, conductive elements, such as fuzz buttons, provided in a non-conductive interposer structure. One skilled in the art will appreciate, however, that any of the various other technologies may be used in lieu of, or in addition to, such LGA technology. Although the preferred embodiments of the present invention are described herein within the context of land grid arrays (LGAs) connector that connect electronic modules to a PCB, one skilled in the art will appreciate that many variations are possible within the scope of the present invention.

Typically, the module substrate 314 is fabricated from a ceramic material and includes conductive attach pads on upper and lower surfaces that are interconnected through conductive vias that extend through the ceramic material.

The fixed-gap cooling plate 102 is hard mounted on the PCB 106 and makes thermal contact with the bare die chips 316 (or module cap or lid) through a relatively thick compressive pad thermal interface material (TIM) 302. As described in more detail below, the fixed-gap cooling plate 102 is hard mounted on the PCB via threaded screws 360 and standoffs 370. The compressive pad TIM 302 may be pre-cured or, alternatively, may be cured in-situ. For example, the compressive pad TIM 302 may be provided by mixing a multi-part liquid material and then applying the mixture to the fixed-gap cooling plate 102 and/or the electronic components. An example of a suitable composition for the compressive pad TIM 302 is a fiberglass reinforced, thermally conductive silicone gel pad, commercially available from Dow Corning Corporation, Midland, Mich. The compressive pad TIM 302 may be a single pad that covers substantially the entire bottom surface of the fixed-gap cooling plate 102, or may include a plurality of pads that are provided on the top surface of the chips 316 and/or at suitable locations on the bottom surface of the fixed-gap cooling plate 102.

The bare die chips 316 are electrically connected to their respective module substrate 314 by, for example, controlled collapse chip connection (C4) solder joints 318. The C4 solder joints 318 include solder balls that electronically connect terminals (not shown) on the flip-chips 316 to corresponding attach pads (not shown) on the module substrates 314. Typically, a non-conductive polymer underfill that encapsulates the C4 solder joints 318 is disposed in the space between the base of each flip-chip 316 and the upper surface of the module substrate 314. One skilled in the art will appreciate, however, that any of the various other technologies may be used in lieu of, or in addition to, such C4 solder joint connector technology. Although the preferred embodiments of the present invention are described herein within the context of C4 solder joint connectors that connect bare die chips to a module substrate, one skilled in the art will appreciate that many variations are possible within the scope of the present invention.

As mentioned above, electronic components are generally packaged using electronic packages (i.e., modules) that include a module substrate, such as module substrates 314, to which the electronic component is electronically connected. In some cases, the module includes a cap (i.e., capped module) or lid (i.e., lidded module) which seals the electronic component within the module. In other cases, the module does not include a cap (i.e., a bare die module). In the case of a capped module (or a lidded module), the coldplate is typically attached with a thermal interface between a bottom surface of the coldplate and a top surface of the cap (or lid), and another thermal interface between a bottom surface of the cap (or lid) and a top surface of the electronic component. In the case of a bare die module, a coldplate is typically attached with a thermal interface between a bottom surface of the coldplate and a top surface of the electronic component.

In addition, a heat spreader (not shown) may be attached to the top surface of each flip-chip to expand the surface area of thermal interface relative to the surface area of the flip-chip. The heat spreader, which is typically made of a highly thermally conductive material such as SiC, is typically adhered to the top surface of the flip-chip with a thermally-conductive adhesive.

Referring again to FIG. 3, a rigid insulator 351 is disposed along the bottom surface of PCB 106 and is preferably fabricated from fiberglass reinforced epoxy resin. In addition, a backside stiffener 352, which is preferably a metal or steel plate, is disposed along the bottom surface of the rigid insulator 351. Threaded screws 360 pass through apertures in backside stiffener 352, rigid insulator 351, PCB 106 and into standoffs 370 provided on the bottom surface fixed-gap cooling plate 102. The standoffs 370 and the fixed-gap cooling plate 102 may have a unitary structure (e.g., the standoffs 370 may be formed on the fixed-gap cooling plate through a milling process) or the standoffs 370 may be formed separately from the fixed-gap cooling plate 102 (e.g. the standoffs 370 may be sleeves inserted over screws 360 between the fixed-gap cooling plate 102 and the PCB 106). In either case, the standoffs 370 and/or the fixed-gap cooling plate 102 are threaded to receive the threaded screws 360.

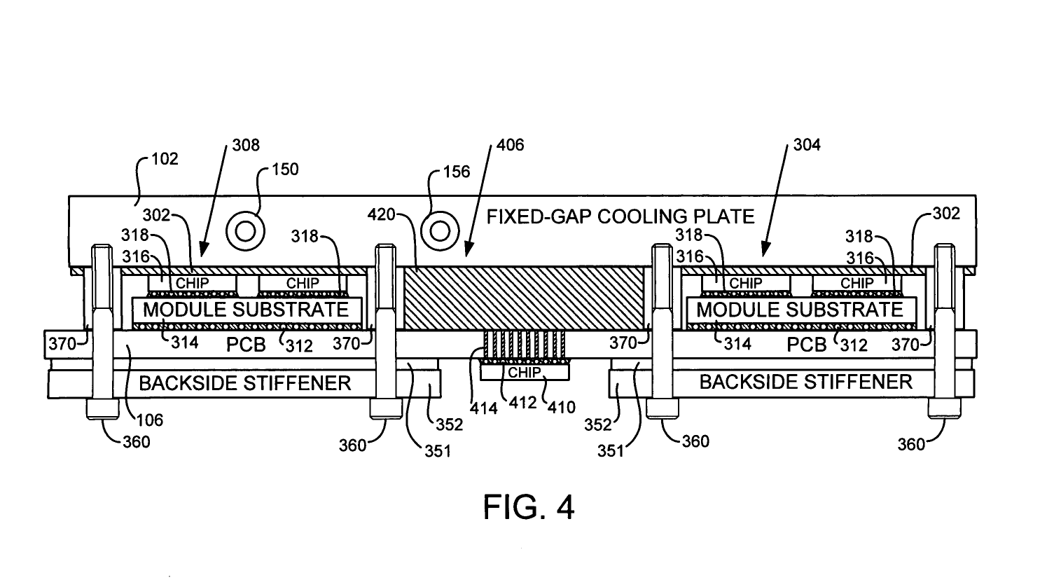

FIG. 4 is a sectional view of a fixed-gap cooling plate portion of a modified version of the cooling plate assembly shown in FIG. 1. FIG. 4 is similar to FIG. 3, except that the fixed-gap cooling plate 102 is used to cool a bottom-side mounted chip 410 in lieu of the topside mounted multi-chip module 306 in FIG. 3. Hence, the chip 410 corresponds to the low power electronic component 114 shown in FIG. 1. It is important to note, however, the flip-chip 410 shown in FIG. 4 is exemplary. Those skilled in the art will appreciate that the methods and apparatus of the present invention can also apply to configurations differing from the chip shown in FIG. 4, to other types of chips and/or connectors, and generally to electronic components.

The chip 410 is in thermal contact with the fixed-gap cooling plate 102 through C4 solder joints 412 that electrically connect the chip to the PCB 106, conductive vias 414 that extend through the PCB 106, and a relatively thick compressive pad TIM 420. The compressive pad TIM 420 may be pre-cured or, alternatively, may be cured in-situ. For example, the compressive pad TIM 420 may be provided by mixing a multi-part liquid material and then applying the mixture to the fixed-gap cooling plate 102 and/or the topside of the PCB 106. An example of a suitable composition for the compressive pad TIM 420 is a fiberglass reinforced, thermally conductive silicone gel pad, commercially available from Dow Corning Corporation, Midland, Mich.

In an embodiment where the compressive pad TIM 302 is a single pad that covers substantially the entire bottom surface of the fixed-gap cooling plate 102, it may be desirable to provide the compressive pad TIM 420 in the form of a compressive spacer-pad TIM interposed between the compressive pad TIM 302 and a suitable location on the topside of the PCB 106.

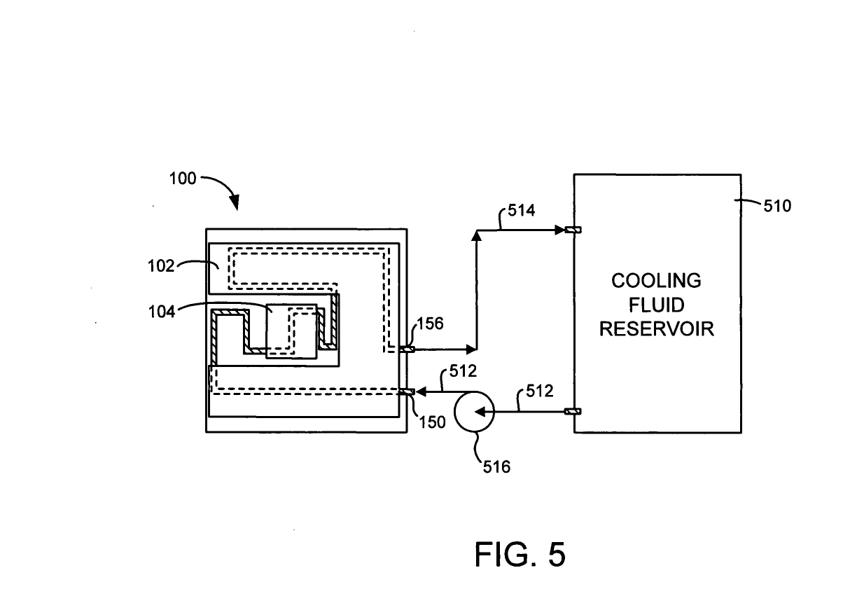

FIG. 5 is a top plan view of a cooling plate assembly 100 having a fixed-gap cooling plate 102 and an articulated cooling plate 104 in fluid communication with a reservoir 510 containing cooling fluid according to the preferred embodiments of the present invention. A cooling fluid is preferably pumped from thermal reservoir 510 through a supply conduit 512 to inlet port 150 of the cooling plate assembly 100, where the cooling fluid picks up heat as it travels through thermal dissipation channels of the fixed-gap cooling plate 102 and the articulated cooling plate 104. Then, the cooling fluid is exhausted from outlet port 156 of the cooling plate assembly 100 through an exhaust conduit 514 and returns to thermal reservoir 510. A pump 516 is preferably provided to force the cooling fluid through the recirculation loop. Prior to recirculating the cooling fluid through the recirculation loop, it may be desirable to cool the cooling fluid. For example, the cooling fluid may be cooled in the reservoir or elsewhere using a heat exchanger, waterfall, radiator, or other conventional cooling mechanism. The cooling fluid may be any suitable coolant, for example, an inert perfluorocarbon fluid, such as 3M Fluorinert™ commercially available from 3M Company, St. Paul, Minn. Other suitable coolants include, but are not limited to, water, ethylene glycol, ethylene glycol/water mixture, polyalphaolefin (PAO), ammonia, methanol, nitrogen, and the like.

In military and other applications where weight is critical (e.g., fighter aircraft, and the like), it may be desirable for the cooling fluid to be provided from a pre-existing system. This reduces the additional weight that must be borne to implement a cooling plate assembly in accordance with the preferred embodiments of the present invention. For example, the cooling fluid may be an aircraft's jet fuel, the reservoir may be the aircraft's fuel tank, and the pump and/or conduits may be a portion of the aircraft's fuel distribution system. In this example, the coolant is flammable, and thus it is critical to minimize the risk of coolant leaking from the tubing. Hence, in such examples where the coolant is flammable, the minimal number of flexible tube interconnects needed to implement a cooling plate assembly in accordance with the preferred embodiments of the present invention not only decreases the risk of leaking (as compared to solutions that require a large number of flexible tube interconnects) and hence decreases the risk of component failure but also decreases the risk of fire.

Supply conduit 512 and exhaust conduit 514 are respectively attached to inlet port 150 and outlet port 156 of the cooling plates assembly 100 using any suitable conventional fastening technique, such as by inserting and sealing tubular fittings into inlet port 150 and outlet port 156, and then mating supply conduit 512 and exhaust conduit 514 over the tubular fittings to provide a tight seal. Supply conduit 512 and exhaust conduit 514 may be rubber, metal or some other suitable material that is compatible with the coolant.

In general, the rate of heat transfer can be controlled by using various thermal transport media in the internal structure of the cooling plate assembly 100. For example, the rate of heat transfer can be controlled by varying the composition and/or the flow rate of the cooling fluid. Also, the rate of heat transfer is a function of the configuration of the thermal dissipation channels within the cooling plate assembly 100.

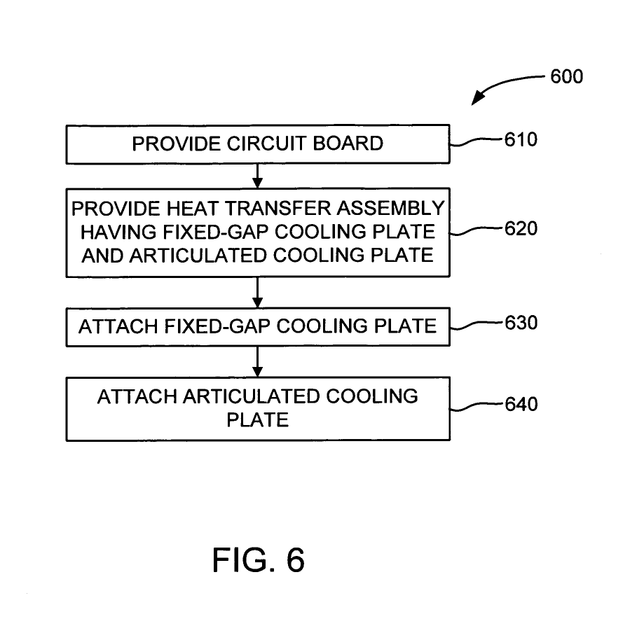

FIG. 6 is a flow diagram of a method 600 for attaching a heat transfer assembly having fixed and articulated interfaces to a circuit board according to the preferred embodiments of the present invention. The method 600 sets forth the preferred order of the steps. It must be understood, however, that the various steps may occur at any time relative to one another. A circuit board is provided on which electronic components are mounted (step 610). In accordance with the preferred embodiments of the present invention, the circuit board is PCB 106 on which are mounted a high power electronic component 130 and low power electronic components 110, 112, 114, 116 and 118.

Also, a heat transfer assembly is provided (step 620). In accordance with the preferred embodiments of the present invention, the heat transfer assembly includes a fixed-gap cooling plate 102, an articulated cooling plate 104, and flexible tubes 162 and 164 interconnecting thermal dissipation channel 140, 142 and 144 of the cooling plates 102 and 104. Preferably, the flexible tubes 162 and 164 are made of copper and include a free-expansion loop to minimize the reaction force imparted between the cooling plates 102 and 104 as the cooling plates are attached. The flexible tubes 162 and 164 may be swaged, soldered and/or brazed to the cooling plates 102 and 104.

The method 600 continues by attaching the fixed-gap cooling plate over and in thermal contact with a plurality of electronic components mounted on a top surface of a circuit board (step 630). In accordance with the preferred embodiments of the present invention, the step 630 includes interposing a compressive pad TIM 302 between the fixed-gap cooling plate 102 and the low power electronic components 110, 112, 114, 116 and 118.

Next, the method 600 continues by attaching the articulated cooling plate over and in thermal contact with at least one electronic component mounted on the top surface of the circuit board (step 640). In accordance with the preferred embodiments of the present invention, the step 640 includes actuating a mechanical attach system, such as post/spring-plate type claming mechanism 250, to provide a spring-loading force that biases the articulated cooling plate 104 in thermal contact with the high power electronic component 130. This spring-loading force is sufficient to overcome the reaction force imparted by the clamping mechanism 250 to the flexible tubes 162 and 164 between the fixed-gap cooling plate 102 and the articulated cooling plate 104.

One skilled in the art will appreciate that many variations are possible within the scope of the present invention. For example, the methods and apparatus of the present invention can also apply to configurations differing from the various multi-chip module assemblies shown in FIGS. 2 and 3, as well as to other types of chip modules and other electronic components. Thus, while the present invention has been particularly shown and described with reference to the preferred embodiments thereof, it will be understood by those skilled in the art that these and other changes in form and detail may be made therein without departing from the spirit and scope of the present invention.

What is claimed is:

1. A cooling plate assembly for transferring heat from a plurality of electronic components mounted on a circuit board, comprising:
a circuit board having a top surface and a bottom surface;
a fixed-gap cooling plate positioned over and in thermal contact with a plurality of electronic components mounted on the top surface of the circuit board and having a thermal dissipation channel extending through a portion thereof;
an articulated cooling plate positioned over and in thermal contact with at least one electronic component mounted on the top surface of the circuit board and having a thermal dissipation channel extending through a portion thereof;
a flexible tube interconnecting the thermal dissipation channel of the fixed-gap cooling plate and the thermal dissipation channel of the articulated cooling plate.

2. The cooling plate assembly as recited in claim 1, wherein the electronic components under the fixed-gap cooling plate are in thermal contact with the fixed-gap cooling plate through a compressive pad thermal interface material (TIM).

3. The cooling plate assembly as recited in claim 2, wherein one or more electronic components are mounted on the bottom surface of the circuit board and are in thermal contact with the fixed-gap cooling plate through one or more thermally conductive elements extending through the circuit board to the compressive pad TIM.

4. The cooling plate assembly as recited in claim 1, wherein the at least one electronic component under the articulated cooling plate has a power dissipation that is higher than that of each of the electronic components under the fixed-gap cooling plate.

5. The cooling plate assembly as recited in claim 1, wherein the electronic components under the fixed-gap cooling plate are in thermal contact with the fixed-gap cooling plate through a compressive pad thermal interface material (TIM), wherein the at least one electronic component under the articulated cooling plate has a power dissipation that is higher than that of each of the electronic components under the fixed-gap cooling plate, and wherein the articulated cooling plate is spring-loaded against the higher power dissipation electronic component and provides a thermal interface that is thinner than the thermal interface provided by the compressive pad TIM between the fixed-gap cooling plate and the electronic components under the fixed-gap cooling plate.

6. The cooling plate assembly as recited in claim 1, wherein the fixed-gap cooling plate has a generally slot-shaped feature and the articulated cooling plate is located substantially inside the slot-shaped feature.

7. The cooling plate assembly as recited in claim 1, wherein the flexible tube comprises at least one of: a flexible tube interconnecting an outlet port of the fixed-gap cooling plate and an inlet port of the articulated cooling plate; and a flexible tube interconnecting an outlet port of the articulated cooling plate and an inlet port of the fixed-gap cooling plate.

8. The cooling plate assembly as recited in claim 1, wherein the fixed-gap cooling plate and the articulated cooling plate each comprise an aluminum plate, and wherein the flexible tube comprises one or more copper tubes with a free-expansion loop.

9. The cooling plate assembly as recited in claim 1, wherein the thermal dissipation channels of the fixed-gap cooling plate and the articulated cooling plate are in fluid communication with a reservoir containing cooling fluid.

10. The cooling plate assembly as recited in claim 9, wherein the reservoir as a fuel tank of an aircraft, and wherein the cooling fluid is jet fuel.

11. A cooling plate assembly for transferring heat from a plurality of electronic components mounted on a circuit board, comprising:
a circuit board having a top surface and a bottom surface, wherein a plurality of electronic components are mounted on the top surface of the circuit board;
a fixed-gap cooling plate having a generally U-shaped configuration comprising a first leg portion and a second leg portion each extending from a base portion, wherein the fixed-gap cooling plate is positioned over and in thermal contact with a plurality of electronic components mounted on the top surface of the circuit board, wherein a first thermal dissipation channel extends through a first portion of the fixed-gap cooling plate from an inlet port at the base portion to an outlet port at the first leg portion, and wherein a second thermal dissipation channel extends through a second portion of the fixed-gap cooling plate from an inlet port at the second leg portion to an outlet port at the base portion;
an articulated cooling plate with a first side and a second side, wherein the articulated cooling plate is positioned over and in thermal contact with at least one electronic component mounted on the top surface of the circuit board between the first and second leg portions of the fixed-gap cooling plate, wherein a thermal dissipation channel extends through the articulated cooling plate from an inlet port at the first side to an outlet port at the second side;
a first flexible tube interconnecting the first thermal dissipation channel of the fixed-gap cooling plate and the thermal dissipation channel of the articulated cooling plate, wherein the first flexible tube connects the outlet port at the first leg portion of the fixed-gap cooling plate to the inlet port at the first side of the articulated cooling plate;
a second flexible tube interconnecting the thermal dissipation channel of the articulated cooling plate and the second thermal dissipation channel of the fixed-gap cooling plate, wherein the second flexible tube connects the outlet port at the second side of the articulated cooling plate to the inlet port at the second leg portion of the fixed-gap cooling plate.

12. The cooling plate assembly as recited in claim 11, wherein the electronic components under the fixed-gap cooling plate are in thermal contact with the fixed-gap cooling plate through a compressive pad thermal interface material (TIM).

13. The cooling plate assembly as recited in claim 12, wherein one or more electronic components are mounted on the bottom surface of the circuit board and are in thermal contact with the fixed-gap cooling plate through one or more thermally conductive elements extending through the circuit board to the compressive pad TIM.

14. The cooling plate assembly as recited in claim 11, wherein the at least one electronic component under the articulated cooling plate has a power dissipation that is higher than that of each of the electronic components under the fixed-gap cooling plate.

15. The cooling plate assembly as recited in claim 11, wherein the electronic components under the fixed-gap cooling plate are in thermal contact with the fixed-gap cooling plate through a compressive pad thermal interface material (TIM), wherein the at least one electronic component under the articulated cooling plate has a power dissipation that is higher than that of each of the electronic components under the fixed-gap cooling plate, and wherein the articulated cooling plate is spring-loaded against the higher power dissipation electronic component and provides a thermal interface that is thinner than the thermal interface provided by the compressive pad TIM between the fixed-gap cooling plate and the electronic components under the fixed-gap cooling plate.

16. The cooling plate assembly as recited in claim 11, wherein the fixed-gap cooling plate and the articulated cooling plate each comprise an aluminum plate, and wherein the flexible tube comprises one or more copper tubes each with a free-expansion loop.

17. The cooling plate assembly as recited in claim 11, wherein the inlet and outlet ports at the base portion of the fixed-gap cooling plate are connected to a reservoir containing cooling fluid that flows through the first thermal dissipation channel of the fixed-gap cooling plate, the first flexible tube, the thermal dissipation channel of the articulated cooling plate, the second flexible tube, and the second thermal dissipation channel of the fixed-gap cooling plate.

18. The cooling plate assembly as recited in claim 17, wherein the reservoir is a fuel tank of an aircraft, and wherein the cooling fluid is jet fuel.

19. A method of attaching a heat transfer assembly to a circuit board for transferring heat from a plurality of electronic components mounted on the circuit board, comprising the steps of:
providing a circuit board having a top surface and a bottom surface;
providing a heat transfer assembly comprising a fixed-gap cooling plate having a thermal dissipation channel extending through a portion thereof, an articulated cooling plate having a thermal dissipation channel extending through a portion thereof, and a flexible tube interconnecting the thermal dissipation channel of the fixed-gap cooling plate and the thermal dissipation channel of the articulated cooling plate;
attaching the fixed-gap cooling plate over and in thermal contact with a plurality of electronic components mounted on the top surface of the circuit board;
attaching the articulated cooling plate over and in thermal contact with at least one electronic component mounted on the top surface of the circuit board.

20. The method as recited in claim 19, wherein the step of attaching the articulated cooling plate includes the step of imparting a reaction force to the flexible tube between the fixed-gap cooling plate and the articulated cooling plate.

21. The method as recited in claim 20, wherein the step of attaching the fixed-gap cooling plate includes the step of interposing a compressive pad thermal interface material (TIM) between fixed-gap cooling plate and the electronic components thereunder, and wherein the step of attaching the articulated cooling plate includes the step of actuating a mechanical attach system to provide a spring-loading force that biases the articulated cooling plate in thermal contact with the at least one electronic component thereunder, the spring-loading force being sufficient to overcome the reaction force imparted by the flexible tube between the fixed-gap cooling plate and the articulated cooling plate.

22. The method as recited in claim 19, wherein the step of providing a heat transfer assembly comprises the steps of:
providing a fixed-gap cooling plate having a first thermal dissipation channel extending through a first portion of the fixed-gap cooling plate from an inlet port to an outlet port and a second thermal dissipation channel extending through a second portion of the fixed-gap cooling plate from an inlet port to an outlet port;
providing an articulated cooling plate having a thermal dissipation channel extending from an inlet port to an outlet port;
providing a first flexible tube having a first end and a second end;
providing a second flexible tube having a first end and a second end;
interconnecting the first thermal dissipation channel of the fixed-gap cooling plate and the thermal dissipation channel of the articulated cooling plate by connecting the first end of the first flexible tube to the outlet port of the first thermal dissipation channel of the fixed-gap cooling plate and connecting the second end of the first flexible tube to the inlet port of the articulated cooling plate;
interconnecting the thermal dissipation channel of the articulated cooling plate and the second thermal dissipation channel of the fixed-gap cooling plate by connecting the first end of the second flexible tube to the outlet port of the articulated cooling plate and connecting the second end of the second flexible tube to the inlet port of the second thermal dissipation channel of the fixed-gap cooling plate.

23. The method as recited in claim 19, wherein the first flexible tube is a copper tube with a free-expansion loop.

24. The method as recited in claim 23, wherein a first end of the copper tube is swaged, soldered and/or brazed to the fixed-gap cooling plate and a second end of the copper tube is at least one of swaged, soldered and/or brazed to the articulated cooling plate.

25. A method of transferring heat from a plurality of electronic components mounted on a circuit board, comprising the steps of:
providing a cooling plate assembly comprising
a circuit board having a top surface and a bottom surface,
a fixed-gap cooling plate positioned over and in thermal contact with a plurality of electronic components mounted on the top surface of the circuit board and having a thermal dissipation channel extending through a portion thereof,
an articulated cooling plate positioned over and in thermal contact with at least one electronic component mounted on the top surface of the circuit board and having a thermal dissipation channel extending through a portion thereof, and
a flexible tube interconnecting the thermal dissipation channel of the fixed-gap cooling plate and the thermal dissipation channel of the articulated cooling plate
moving a cooling fluid through the thermal dissipation channel of the fixed-gap cooling plate, the flexible tube and the thermal dissipation channel of the articulated cooling plate.
